(19) United States
(12) Patent Application Publication
(10) Pub. No.: US 2008/0115914 A1
(43) Pub. Date: May 22, 2008

(54) HEAT DISSIPATION DEVICE WITH HEAT PIPES

(75) Inventors: BO-YONG YANG, Shenzhen (CN); SHIH-HSUN WUNG, Taipei Hsien (TW); CHUN-CHI CHEN, Taipei Hsien (TW)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Taipei Hsien (TW)

(21) Appl. No.: 11/561,357

(22) Filed: Nov. 17, 2006

(51) Int. Cl. H05K 7/20

(52) U.S. Cl. 165/104.33; 165/80.3; 361/700

(57) ABSTRACT

A heat dissipation device includes a base, a plurality of first fins, a plate with a plurality of second fins, a plurality of third fins, three heat pipes and a fan assembly. Each heat pipe includes a heat-receiving portion sandwiched between the base and the first fins, a heat-exchange portion sandwiched between the plate and the first fins, a connecting portion connecting the heat-receiving portion and the heat-exchange portion, a heat-discharging portion extending through the plate and inserted into the third fins. The fan assembly is arranged beside the first, second and third fins and generates forced airflow flowing into channels defined by the first, second and third fins.

### CROSS-REFERENCES TO RELATED APPLICATION

Relevant subject matter is disclosed in a co-pending U.S. patent application Ser. No. 11/263,322, filed on Oct. 31, 2005 and entitled “HEAT DISSIPATION DEVICE HAVING HEAT PIPE”, which is assigned to the same assignee as this application. The disclosures of the co-pending application are wholly incorporated herein by reference.

### BACKGROUND OF THE INVENTION

1. Field of the Invention

The present invention relates generally to a heat dissipation device, and more particularly to a heat dissipation device for cooling a heat-generating electronic device, having heat pipes configured for enhancing heat dissipation capability thereof.

2. Description of Related Art

It is widely acknowledged that heat is produced during operation of electronic devices such as central processing units (CPUs). The heat produced must be quickly removed to ensure normal operation of the CPU. Typically, a heat sink is provided to remove heat from the CPU. The greater the number of electronic components integrated on the CPU, the hotter the CPU becomes during operation. The conventional heat sink, which is made of a simple slotted metal block attached to the CPU, is no longer a satisfactory means for dissipating heat from the CPU.

Phase change equipment, such as heat pipes have been developed to assist heat management of the heat-generating electronic device. Generally, a heat dissipation device with heat pipe comprises a base to absorb heat from the electronic device, a plurality of fins extending from the base and two heat pipes. Each heat pipe comprises an evaporator engaging with the base and a condenser engaging with the fins. During operation of the heat dissipation device, the base absorbs the heat from the electronic device. One part of the heat is directly transferred to bottom portions of the fins. The other part of the heat is transferred to top portions of the fins via the heat pipes.

However, the heat pipes cannot be optimally utilized in the conventional heat dissipation device. On the one hand if the evaporators of the heat pipes are separated from each other by too great a distance they will be incapable of sufficiently absorbing the heat from the heat-generating electronic device. On the other hand, if the condensers of the heat pipes are separated from each other by too small a distance, the condensers will distribute the heat transferred from the evaporators to the top portions of the fins unevenly. Although the above problem can be resolved, a width of the fins must be increased significantly in order to accommodate the condensers of the heat pipes. The increase of the width of the fins is quite disadvantageous in view of a compact design of the heat dissipation device for transportation, storage and installation. Summarily, the conventional heat dissipation device with heat pipes cannot simultaneously meet the requirements that the evaporators focus at the central portion of the base of the heat dissipation device to efficiently remove the heat from the base, and that the condensers can evenly distribute the heat to the fins without increasing the width of the fins.

### SUMMARY OF THE INVENTION

A heat dissipation device in accordance with a preferred embodiment of the present invention includes a base, first fins, a plate with second fins, third fins stacked on top of the second fins. The heat dissipation device further includes three heat pipes and a fan assembly. Each heat pipe includes a heat-receiving portion sandwiched between the base and the first fins, a heat-exchange portion sandwiched between the plate and the first fins, a connecting portion connecting the heat-receiving portion and the heat-exchange portion, a heat-discharging portion extending through the plate and inserted into the third fins. The fan assembly is arranged beside the third fins and generates forced airflow flowing into channels defined by the three fins. The heat-receiving portions of the heat pipes are located at a center of the base, while the heat-discharging portions are located near opposite sides of the third fins.

Other advantages and novel features will become more apparent from the following detailed description of preferred embodiments when taken in conjunction with the accompanying drawings, in which:

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded, isometric view of a heat dissipation device according to a preferred embodiment of the present invention;

FIG. 2 is a pre-assembled view of FIG. 1; and

FIG. 3 is an assembled view of FIG. 1.

### DETAILED DESCRIPTION OF THE INVENTION

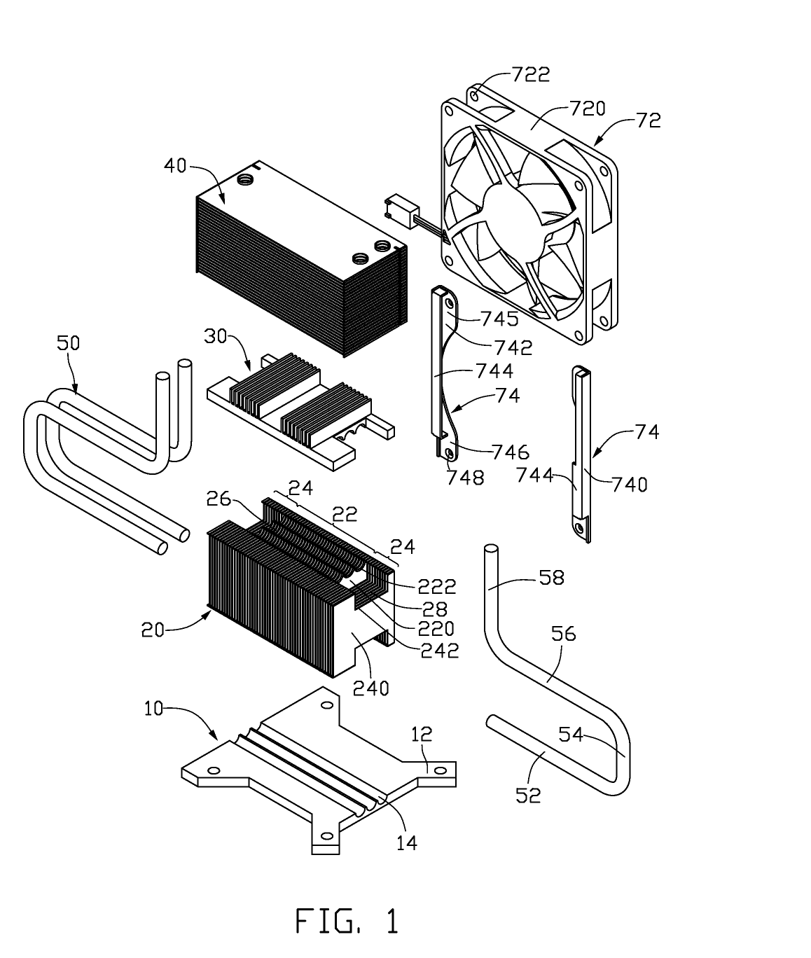

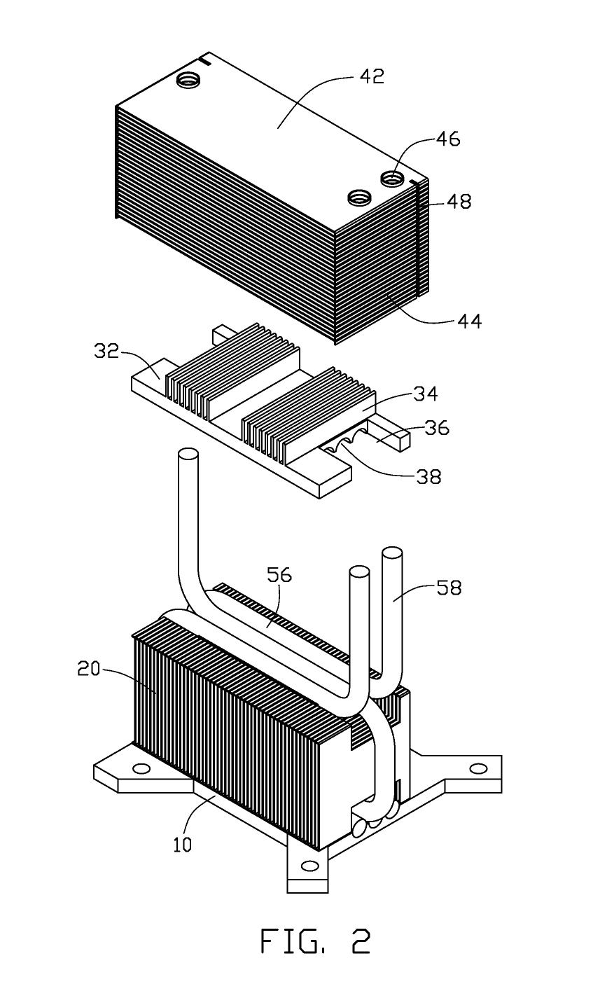

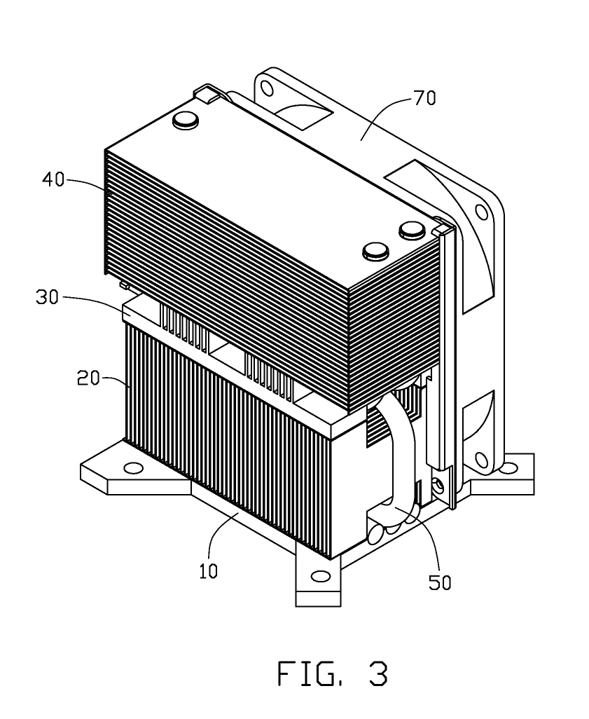

Referring to FIGS. 1-3, a heat dissipation device of the preferred embodiment of the present invention is mounted to a printed circuit board (not shown) to remove heat from a heat-generating electronic device (not shown) mounted on the printed circuit board, such as a CPU. The heat dissipation device comprises a base 10, first, second and third heat-dissipation portions 20, 30 and 40 stacked one on another in that order, three heat pipes 50 and a fan assembly 70 arranged at a rear face of the third heat-dissipation portion 40.

The base 10 is a metal plate having a high heat conductivity, and has a rectangular configuration. The base 10 comprises a bottom surface (not labeled) for contacting the electronic device and a top surface (not labeled) opposite the bottom surface. The base 10 forms four fastening ears 12 at four corners thereof. Three parallel grooves 14 are defined in the top surface thereof, for receiving the heat pipes 50. The three grooves 14 are closely spaced, and located at a center of the base 10.

The first heat-dissipation portion 20 comprises a big fin group 24 and two (upper and lower) small fin groups 22 attached to top and bottom surfaces of the big fin group 24, respectively. In FIG. 1 only the upper small fin group 22 attached to the top surface of the big fin group 24 is shown. The big fin group 24 comprises a plurality of vertical first fins 240 attached to the base 10 and defines a pair of recesses 28 at a top and bottom thereof, wherein the upper and lower small fin groups 22 are received. Each first fin 240 is made of a metal sheet and forms a pair of first flanges 242 perpendicularly extending from top and bottom edges thereof. Each of the small fin groups 22 comprises a plurality of vertical first fins 220 and each fin 220 forms a first flange 222 perpendicularly extending from a top edge thereof. Three slots 26 are defined in each small fin group 22 and are located corresponding to the positions of the grooves 14. The slots 26 of the lower small fin group 22 cooperate with the grooves 14 to form passages (not shown) when the first heat-dissipation portion 20 is soldered to the top surface of the base 10.

The second heat-dissipation portion 30 is a metal plate having high heat conductivity. The second heat-dissipation portion 30 comprises a plate 32 and a plurality of vertical second fins 34 extending perpendicularly and upwardly from the plate 32. The plate 32 defines a pair of openings 36 at opposite ends thereof and three flutes 38 at a bottom thereof corresponding to the slots 26 of the first heat-dissipation portion 20. A bottom of the plate 32 is attached on the first flanges 242 of the big fin group 24. The three flutes 38 and the three corresponding slots 26 form three passages (not labeled).

The third heat-dissipation portion 40 comprises a plurality horizontal third fins 42 parallel to the plate 32 and the base 10. The third fins 42 are horizontally stacked on each other to form a horizontal fin group. Each third fin 42 forms a pair of third flanges 44 perpendicularly extending from opposite sides thereof. The third heat-dissipation portion 40 defines three through holes 46 therein and a pair of slits 48 at opposite end edges of the rear face thereof. One of the three through holes 46 is arranged in one side of each third fin 42 opposite the others.

Each heat pipe 50 comprises a horizontal heat-receiving portion (evaporator) 52, a connecting portion 54 extending perpendicularly and vertically upwardly from the heat-receiving portion 52, a heat-exchange portion 56 extending perpendicularly and horizontally from the connecting portion 54 and parallel to the heat-receiving portion 52, and a heat-discharging portion 58. The heat-exchange portion 56 and the heat-discharging portion 58 cooperatively form a condenser for the first heat pipe 50 and have an L-shaped configuration. The heat-discharging portion 58 is extended perpendicularly and vertically upwardly from the heat-exchange portion 56 and parallel to the connecting portion 54.

The fan assembly 70 comprises a fan 72 and a fan holder 74 for securing the fan 72 at the rear face of the third heat-dissipation portion 40. The fan holder 74 comprises a pair of brackets (not labeled) attached to the two lateral sides of the rear face of the third heat-dissipation portion 40. Each bracket comprises a main body 740. A substantially C-shaped fixing faceplate 742 and a positioning rib 744 perpendicularly extends from opposing lateral edges of the main body 740, respectively. The faceplate 742 comprises a tab 745 and an ear 746 at upper and lower parts thereof, respectively. An indentation (not labeled) is defined between the tab 745 and the ear 746. A thread aperture 748 is defined in each of the tab 745 and the ear 746. The fan 72 comprises a rectangular frame 720. The frame 720 defines four orifices 722 in four corners corresponding to the thread apertures 748 of the faceplate 742 of the brackets of the fan holder 74. Screws (not shown) are used to extend through the orifices 722 of the fan 72 and screwed into the thread apertures 748 whereby the fan 72 is mounted to the fan holder 74. Airflow generated by the fan 72 flows through channels (not labeled) respectively defined in the three heat-dissipation portions, 20, 30 and 40 to take heat away therefrom. In assembly the fan holder 74 to the rear face of the third heat-dissipation portion 40, the ribs 744 of the brackets of the fan holder 74 are inserted in corresponding slits 48 of the third heat-dissipation portion 40. The faceplates 742 of the brackets are located on the rear face of the third heat-dissipation portion 40. In this way the two brackets are fixed to the third heat-dissipation portion 40 with the two faceplates 742 thereof extending toward each other.

In assembly of the heat dissipation device, one of the three heat pipes 50 is located opposite the others. The heat-receiving portions 52 are soldered in the passages defined by the grooves 14 of the base 10 and the slots 26 of the bottom of the first heat-dissipation portion 20, wherein the heat-receiving portions 52 are extended into the passages from opposite sides of the base 10 and the first heat-dissipation portion 20 combination, respectively. The bottom of the first heat-dissipation portion 20 is soldered to the top surface of the base 10 and thermally contact with the base 10 and the heat-receiving portions 52 of the heat pipes 50. The first flanges 242 of the first heat-dissipation portion 20 thermally contact the top surface of the base 10 and a bottom surface of the plate 32 to directly exchange heat with the base 10 and the plate 32. The connecting portions 54 are disposed at opposite sides of the first heat-dissipation portion 20. The heat-exchange portions 56 extend into the passages (not labeled) defined by the slots 26 of the small fin group 22 of the first heat-dissipation portion 20 and the flutes 38 of the plate 32 of the second heat-dissipation portion 30, from opposite sides of the first heat-dissipation portion 20 respectively, and are soldered therein and thermally contact the plate 32 and the top of the first heat-dissipation portion 20. The plate 32 is soldered to the top of the first heat-dissipation portion 20. The heat-discharging portions 58 extend through the openings 36 of the plate 32 and extend into the through holes 46 of the third heat-dissipation portion 40. A bottom of the third heat-dissipation portion 40 is attached to the second fins 34 on the plate 32.

The heat-receiving portions 52 are positioned adjacent the centre of the base 10. The heat-exchange portions 56 are attached to the top of the first heat-dissipation portion 20 and the bottom of second heat-dissipation portion 30. The heat-discharging portions 58 extend in the through holes 46 at opposite sides of the horizontal fins 42. As a result, the heat-receiving portions 52 of the heat pipes 50 absorb heat accumulated on the centre of the base 10. A part of the heat absorbed by the base 10 is received by the heat-receiving portions 52 of the heat pipes 50 and transferred to the top of the first heat-dissipation portion 20 and the bottom of the second heat-dissipation portion 30 via the heat-exchange portions 56 of the heat pipes 50, and distributed to the top portion of the first heat-dissipation portion 20 and the bottom of the plate 32. The part of the heat received by the heat pipes 50 from the base 10 is further transferred from the heat-exchange portions 56 to the heat-discharging portions 58. From the heat-discharging portions 58, the part of the heat is transferred to and distributed over the third fins 42 via a thermal contact between the heat-discharging portions 58 and the third fins 42. The other part of the heat is directly transferred to bottom portions of the first heat-dissipation portion 20 from the base 10. In the present invention design, the heat-receiving portions 52 of the heat pipes 50 can be located in a heat-intensive area of the base 10, and the condensers 56, 58 can sufficiently contact with the first and third heat-dissipation portions 20, 40, without increasing width of the heat dissipation device. The present invention provides a compact heat dissipation device which can efficiently remove heat from an up-to-date heat-generating electronic device.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device comprising:
a base;
a plurality of first fins attached to the base;
a plate attached on the first fins and a plurality of second fins extending from the plate;
a plurality of third fins attached to the second fins;
a plurality of heat pipes each comprising a heat-receiving portion sandwiched between the base and the first fins, a heat-exchange portion sandwiched between the plate and the first fins, a connecting portion connecting the heat-receiving portion and the heat-exchange portion, and a heat-discharging portion extending through the plate and inserted into the third fins; and
a fan assembly comprising a fan and a fan holder being inserted into the third fins to mount the fan on a side of all the third fins;
wherein the first, second and third fins define channels in a same direction, thereby allowing forced airflow from the fan to flow to all the channels.

2. The heat dissipation device as claimed in claim 1, wherein the first and second fins are aligned perpendicularly to the base and the plate, and the third fins are aligned parallel to the base and the plate and wherein the channels are oriented parallel to the base and are defined through opposite ends of the heat dissipation device.

3. The heat dissipation device as claimed in claim 2, wherein the base defines parallel grooves therein and the first fins define slots at a bottom thereof, the grooves and the slots commonly define passages to receive the heat-receiving portions of the heat pipes.

4. The heat dissipation device as claimed in claim 1, further comprising a fin group recessed in a top portion of the first fins.

5. The heat dissipation device as claimed in claim 4, wherein the plate defines parallel flutes therein and the fin group defines slots at a top thereof, the flutes and the slots commonly define passages to receive the heat-exchange portions of the heat pipes.

6. The heat dissipation device as claimed in claim 1, wherein the plate defines two openings at two opposite ends thereof through which the heat-discharging portions of the heat pipes extend, respectively.

7. The heat dissipation device as claimed in claim 6, wherein the third fins define through holes therein corresponding to the openings, the heat-discharging portions of the heat pipes being inserted into the through holes, respectively.

8. The heat dissipation device as claimed in claim 1, wherein the third fins define a pair of slits in opposite lateral sides thereof, the fan holder being inserted into the slits.

9. The heat dissipation device as claimed in claim 8, wherein the fan holder comprises a pair of brackets and each bracket forms a positioning rib, the positioning ribs being inserted into the slits.

10. The heat dissipation device as claimed in claim 1, wherein the heat-discharging portions are perpendicular to the third fins and wherein the heat-receiving portions are parallel to the third fins.

11. The heat dissipation device as claimed in claim 10, wherein the connecting portions of the heat pipes are disposed at two opposite sides of the first fins.

12. A heat dissipation device comprising:
a base;
a plurality of first fins attached to the base;
a plate attached on the first fins and a plurality of second fins disposed on the plate;
a plurality of third fins attached on the second fins;
a plurality of heat pipes each comprising a heat-receiving portion sandwiched between the base and the first fins, a heat-exchange portion sandwiched between the plate and the first fins, a connecting portion connecting the heat-receiving portion and the heat-exchange portion, a heat-discharging portion extending through the plate and inserted into the third fins; and
a fan assembly producing forced airflow flowing through channels defined by the three fins;
wherein the first and second fins extend in a first direction and the third fins extend at a second direction different from the first direction.

13. The heat dissipation device as claimed in claim 12, wherein the first and second fins are oriented vertically to the base and the third fins are oriented horizontally to the base.

14. The heat dissipation device as claimed in claim 12, wherein the heat-discharging portions of the heat pips are located at opposite sides of the third fins.
